(19) United States
(12) Patent Application Publication
(10) Pub. No.: US 2003/0123216 A1
(43) Pub. Date: Jul. 3, 2003

(54) Deposition of tungsten for the formation of conformal tungsten silicide

(76) Inventors: Hyungsuk A. Yoon, San Jose, CA (US); Hui Zhang, Santa Clara, CA (US); Michael X. Yang, Palo Alto, CA (US); Ken Kaung Lai, Milpitas, CA (US); Robert L. Jackson, San Jose, CA (US); Alfred W. Mak, Union City, CA (US); Ming Xi, Palo Alto, CA (US)

Correspondence Address: Patent Counsel, Applied Materials, Inc., P.O. Box 450A, Santa Clara, CA, 95052, US

(21) Appl. No.: 10/033,545

(22) Filed: Dec. 27, 2001

(51) Int. Cl. H01L 29/94

(52) U.S. Cl. 361/303

(57) ABSTRACT

A method and apparatus of depositing a tungsten film by cyclical deposition in the formation of tungsten silicide for use in capacitor structures is provided. One embodiment of forming an electrode for a capacitor structure comprises depositing a polysilicon layer over a structure and depositing a tungsten layer over the polysilicon layer by cyclical deposition. The tungsten layer is annealed to form a tungsten silicide layer from the polysilicon layer and the tungsten layer. The tungsten silicide layer acts as one electrode in the capacitor structure. In one aspect, the tungsten silicide layer may be used to form three-dimensional capacitor structures, such as trench capacitors, crown capacitors, and other types of capacitors. In another aspect, the tungsten silicide layer may be used to form capacitor structures which comprise a hemi-spherical silicon grain layer or a rough polysilicon layer.

### BACKGROUND OF THE INVENTION

1. Field of the Invention

Embodiments of the present invention generally relate to methods and apparatuses for depositing a tungsten film by cyclical deposition techniques. More particularly, embodiments of the present invention relate to methods and apparatuses for depositing a tungsten film by cyclical deposition technique in the formation of tungsten silicide for use in capacitor structures.

2.. Description of the Related Art

Dynamic random-access memory (DRAM) integrated circuits are commonly used for storing data in a digital computer. Currently available DRAMs may contain over 16 million memory cells fabricated on a single silicon chip, and each memory cell generally comprises a single transistor connected to a micron or sub-micron sized capacitor. In operation, each capacitor may be individually charged or discharged in order to store one bit of information. To facilitate construction of 64 Mbit, 256 Mbit, 1 Gbit, and larger DRAMs, smaller memory cells with smaller capacitor structures are needed. One limitation to reducing the size of memory cells is that the capacitors must have enough capacitance for reliable storage ability.

Three-dimensional capacitors, such as trench capacitors and crown capacitors, are types of capacitor structures being explored to increase the amount of charge which can be stored per surface area of a semiconductor substrate. In general, three-dimensional capacitors comprise non-planar electrodes which have increased surface area and thus increased capacitance in comparison to planar electrodes. FIG. 1 is a schematic cross sectional view of a prior art three-dimensional trench capacitor 2. The trench capacitor 2 is formed in a trench 4 etched vertically into the surface of a silicon substrate 6. An insulating layer 7 comprising a dielectric material is formed over the trench 2, and a polysilicon layer 8 is formed over the insulating layer 7. The silicon substrate 6 acts as a first electrode and the polysilicon layer 8 acts as the second electrode in the trench capacitor 2. In one aspect, the trench capacitor 2 occupies a smaller area on the surface of the substrate 6 in comparison to a planar capacitor. Therefore, it is desirable to form trench capacitors in trench structures having openings with reduced widths to increase the amount of charge stored per surface area of semiconductor substrate. In another aspect, the capacitance of the trench capacitor 2 increases as the depth of the trench 4 increases due to the increased surface area of the electrodes. Therefore, it is also desirable to form trench capacitors in trench structures with higher aspect ratios to increase the capacitance of the trench capacitors. With other types of three-dimensional capacitors, it is also desirable to form capacitors over structures with aggressive geometries, such as over openings having reduced widths and having high aspect ratios.

However, conventional chemical vapor deposition techniques are inadequate in depositing material conformally in the formation of three-dimensional capacitors over structures having aggressive geometries, such as over structures having openings of about 0.15 μm or less and having an aspect ratio of about 15:1 or more, especially at the bottom of these structures. Conventional chemical vapor deposition techniques may cause material to build up on the top edge of the openings of these structures resulting in the closing off of the opening and the formation of a void.

Therefore, there exists a need for an improved method and apparatus of forming capacitor structures.

### SUMMARY OF THE INVENTION

Embodiments of the present invention generally relate to methods and apparatuses for depositing a tungsten film by cyclical deposition techniques. More particularly, embodiments of the present invention relate to methods and apparatuses for depositing a tungsten film by cyclical deposition techniques in the formation of tungsten silicide for use in capacitor structures.

One embodiment of forming an electrode for a capacitor structure comprises depositing a polysilicon layer over a structure and depositing a tungsten layer over the polysilicon layer by cyclical deposition techniques. The tungsten layer is annealed to form a tungsten silicide layer from the polysilicon layer and the tungsten layer. The tungsten silicide layer acts as one electrode in the capacitor structure. In one aspect, the tungsten silicide layer may be used to form three-dimensional capacitor structures, such as trench capacitors, crown capacitors, and other types of capacitors. In another aspect, the tungsten silicide layer may be used to form capacitor structures which comprise a hemi-spherical silicon grain layer or a rough polysilicon layer.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 is a schematic cross sectional view of a prior art three-dimensional trench capacitor.

FIG. 2 is a schematic cross sectional view of one exemplary embodiment of a processing system adapted to perform cyclical deposition.

FIGS. 3A-3D are cross-sectional views of a substrate illustrating one embodiment of the sequential fabrication steps in the formation of a capacitor.

FIGS. 4A-D are simplified drawings illustrating one embodiment of the alternating adsorption of monolayers of a tungsten containing compound and of monolayers of a reducing gas on a structure.

FIGS. 5A-C are cross-sectional views of a substrate illustrating another embodiment of the sequential fabrication steps in the formation of a capacitor.

FIG. 6 is a schematic top view of one example of a multi-chamber processing system.

FIGS. 7A-B are cross sectional views of a substrate illustrating still another embodiment of the sequential fabrication steps in the formation of a capacitor.

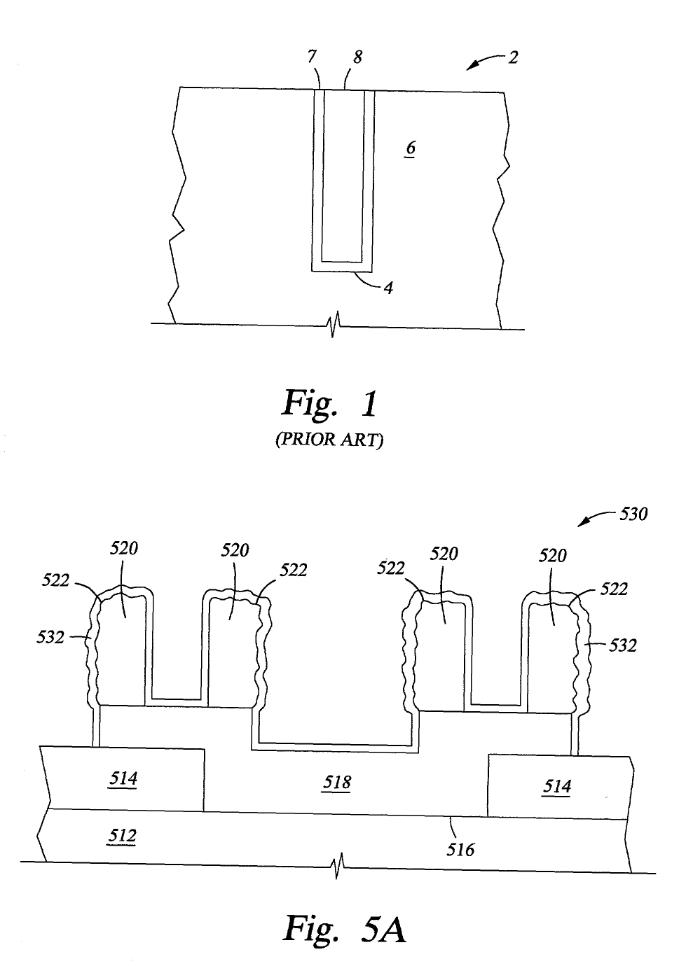

### DETAILED DESCRIPTION OF THE PREFERRED EMBODIMENT

Process Chamber Adapted for Cyclical Deposition of Tungsten

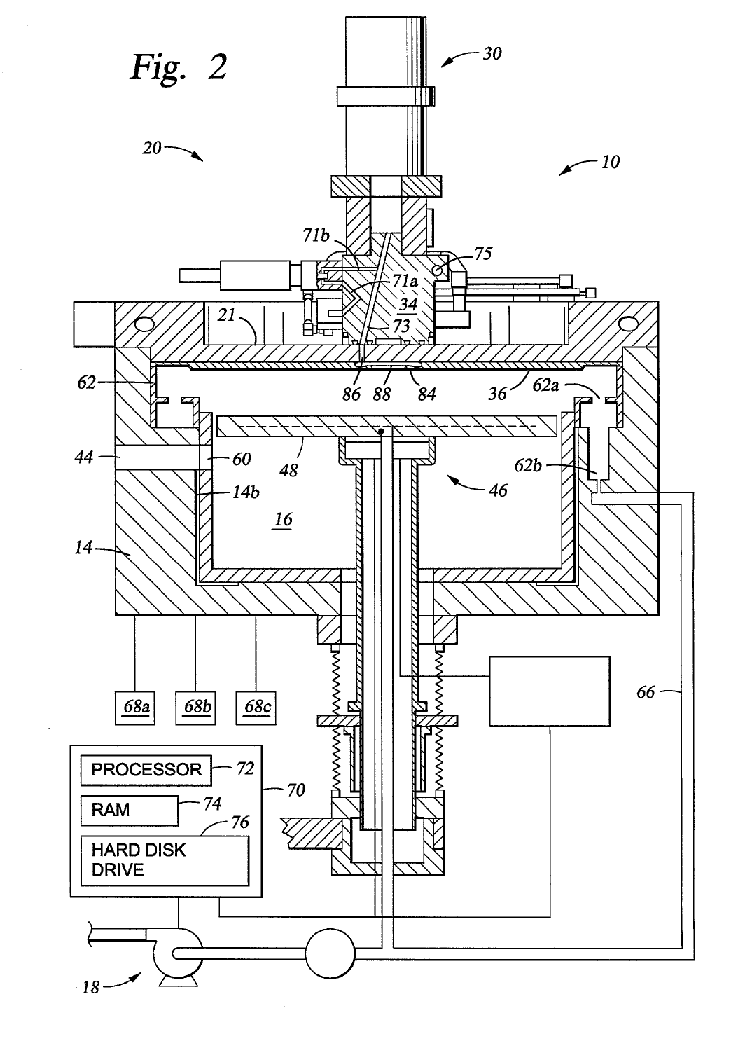

FIG. 2 is a schematic cross-sectional view of one exemplary embodiment of a processing system 10 that may be used to deposit tungsten by cyclical deposition techniques in accordance with aspects of the present invention. The term “cyclical deposition” as used herein refers to the sequential introduction of reactants to deposit a thin layer over a structure and includes processing techniques such as atomic layer deposition and rapid sequential chemical vapor deposition. The sequential introduction of reactants may be repeated to deposit a plurality of thin layers to form a conformal layer to a desired thickness. More than one of the reactants may be present in the chamber at the same time during the sequential introduction of reactants. Alternatively, only one of the reactants may be present in the chamber at one time during the sequential introduction of reactants. The present invention also includes depositing tungsten by cyclical deposition techniques utilizing other processing systems.

The processing system 10 of FIG. 2 includes a housing 14 defining a processing chamber 16 with a slit valve opening 44 and a vacuum lid assembly 20. Slit valve opening 44 allows transfer of a wafer (not shown) between processing chamber 16 and the exterior of system 10. Any conventional wafer transfer device may achieve the aforementioned transfer.

The vacuum lid assembly 20 includes a lid 21 and a process fluid injection assembly 30 to deliver reactive (i.e. precursor, reductant, oxidant), carrier, purge, cleaning and/or other fluids into the processing chamber 16. The fluid injection assembly 30 includes a gas manifold 34 mounting a plurality of control valves 32 (one is shown in FIG. 2), and a baffle plate 36. Programmable logic controllers may be coupled to the control valves 32 to provide sequencing control of the valves. Valves 32 provide rapid gas flows with valve open and close cycles of less than about one second, and in one embodiment, of less than about 0.1 second. In one embodiment, the valves 32 are surface mounted, electronically controlled valves, such as electronically controlled valves available from Fujikin of Japan as part number FR-21-6.35 UGF-APD. Other valves that operate at substantially the same speed may also be used.

The lid assembly 20 may further include one or more gas reservoirs (not shown) which are fluidically connected between one or more process gas sources (such as vaporized precursor sources) and the gas manifold 34. The gas reservoirs may provide bulk gas delivery proximate to each of the valves 32. The reservoirs are sized to insure that an adequate gas volume is available proximate to the valves 32 during each cycle of the valves 32 during processing to minimize time required for fluid delivery thereby shortening sequential deposition cycles. For example, the reservoirs may be about 5 times the volume required in each gas delivery cycle.

The vacuum lid assembly 20 may include one or more valves, such as three valves 32. Two of the valves 32 are fluidly coupled to two separate process gas sources. One of the valves 32 is fluidly coupled to a purge gas source. Each valve 32 is fluidly coupled to a separate trio of gas channels 71a, 71b, 73 (one trio is shown in FIG. 2) of the gas manifold 34. Gas channel 71 a provides passage of gases through the gas manifold 34 to the valves 32. Gas channel 71b delivers gases from the valves 32 through the gas manifold 34 and into a gas channel 73. Channel 73 is fluidly coupled to a respective inlet passage 86 disposed through the lid 21. Gases flowing through the inlet passages 86 flow into a plenum or region 88 defined between the lid 21 and the baffle plate 36 before entering the chamber 16. The baffle plate 36 is utilized to prevent gases injected into the chamber 16 from blowing off gases adsorbed onto the surface of the substrate. The baffle plate 36 may include a mixing lip 84 to re-direct gases toward the center of the plenum 88 and into the process chamber 16.

Disposed within processing chamber 16 is a heater/lift assembly 46 that includes a wafer support pedestal 48. The heater/lift assembly 46 may be moved vertically within the chamber 16 so that a distance between support pedestal 48 and vacuum lid assembly 20 may be controlled. The support pedestal may include an embedded heater element, such as a resistive heater element or heat transfer fluid, utilized to control the temperature thereof. Optionally, a substrate disposed on the support pedestal 48 may be heated using radiant heat. The support pedestal 48 may also be configured to hold a substrate thereon, such as by a vacuum chuck, by an electrostatic chuck, or by a clamp ring.

Disposed along the side walls 14b of the chamber 16 proximate the lid assembly 20 is a pumping channel 62. The pumping channel 62 is coupled by a conduit 66 to a pump system 18 which controls the amount of flow from the processing chamber 16. A plurality of supplies 68a, 68b and 68c of process and/or other fluids, are in fluid communication with one of valves 32 through a sequence of conduits (not shown) formed through the housing 14, lid assembly 20, and gas manifold 34. The processing system 10 may include a controller 70 which regulates the operations of the various components of system 10.

Capacitor Fabrication

The present invention relates to methods for depositing a tungsten film by cyclical deposition techniques in the formation of tungsten silicide for use in capacitor structures. It is believed that the mode of deposition of an ALD tungsten film provides conformal coverage over structures. Therefore, a tungsten silicide film can be formed from an ALD tungsten film over structures having aggressive geometries, such as structures with openings having reduced widths and having higher aspect ratios. The present invention may be used to advantage in forming a tungsten silicide electrode in three-dimensional capacitors, such as trench capacitors, crown capacitors, or other capacitors.

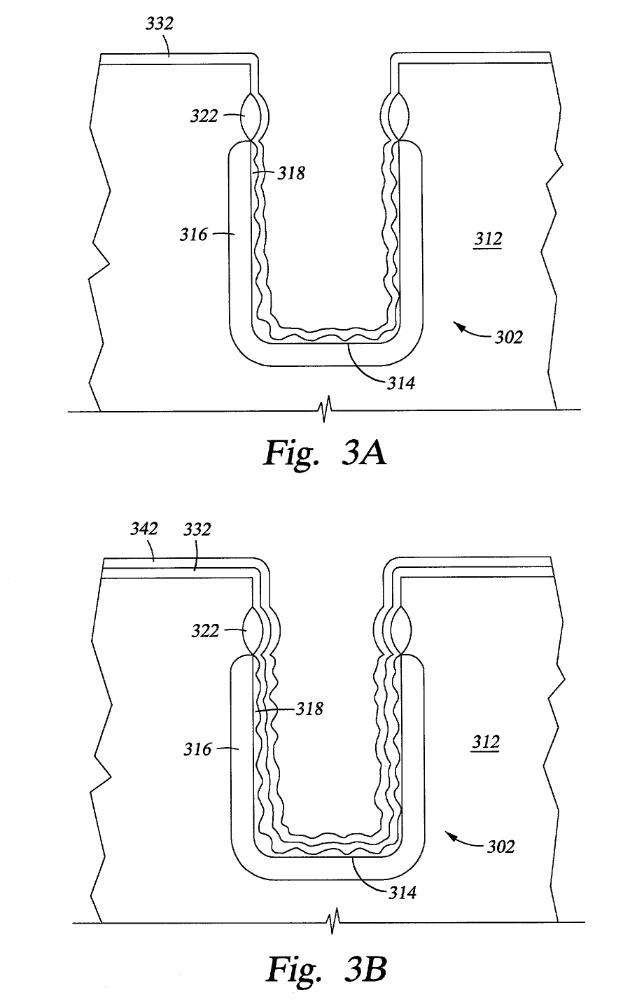

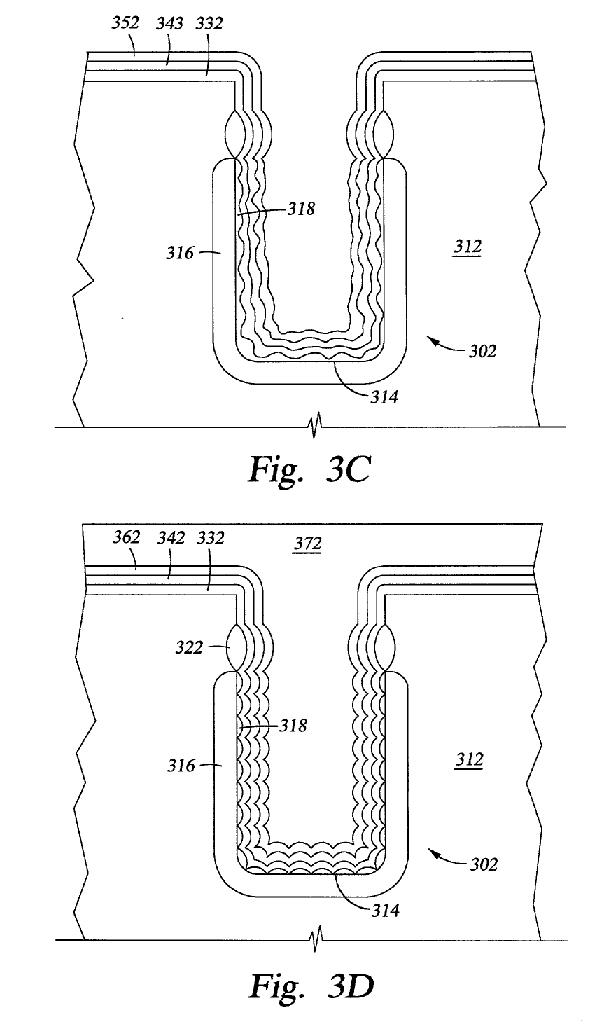

Not wishing to be bound by theory, FIGS. 3A-3D are cross-sectional views of a substrate illustrative of one possible capacitor structure. The present invention also includes embodiments directed to other capacitor structures. FIG. 3A shows a structure 302 at one stage in the formation of a trench capacitor. In this embodiment, the structure 302 comprises a substrate 312 having a trench 314 formed therein by patterning and etching, such as a silicon substrate, germanium substrate, or a gallium arsenide substrate. In another embodiment, the structure comprises a conductive layer, such as a polysilicon layer, deposited over a trench formed in a dielectric layer.

The bottom and the lower sidewalls of the trench 314 are doped with arsenic, antimony, phosphorus, boron, or other dopants to formed doped areas 316. The doped areas 316 act as a buried first electrode in the trench capacitor. The structure 302 may include a collar 322, such as a silicon oxide collar, to server as an insulating layer in the final device structure. A hemi-spherical silicon grain layer (HSG) 318 or a rough polysilicon layer may be optionally formed over the doped areas 316 to increase the surface area of the first electrode. One example of forming a hemi-spherical silicon grain layer or a rough polysilicon layer comprises depositing an amorphous silicon layer. The amorphous silicon layer is annealed to transform the amorphous silicon layer to a polysilicon layer having a rough surface. The hemi-spherical silicon grain layer 318 may also be doped.

The structure 302 further includes an insulating layer 332 comprising a dielectric material, such as tantalum pentoxide (Ta₂O₅), silicon oxide/silicon nitride/oxynitride (“ONO”), and other dielectric materials including high dielectric constant materials. In one aspect, the insulating layer 332 preferably comprises Ta₂O₅ or other high dielectric constant materials because a high dielectric constant material allows the insulating layer 332 to be thinner and thus allows for larger capacitance densities. Examples of other high dielectric constant materials include, but are not limited to, barium strontium titanate, barium titanate, lead zirconate titanate, lead lanthanium titanate, strontium titanate, and strontium bismuth titanate.

FIG. 3B shows a polysilicon layer 342 deposited over the structure 302 of FIG. 3A. Any suitable method and apparatus may be used to deposit the polysilicon layer 342. For example, the polysilicon layer 342 may be deposited by chemical vapor deposition utilizing a Polygen Centura™ chamber, commercially available from Applied Materials, Inc., located in Santa Clara, Calif. One exemplary process regime for depositing the polysilicon layer comprises flowing silane (SiH₄) into the chamber to thermally decompose to polysilicon over the structure 302. The substrate 312 is heated to a substrate temperature between about 550° C. and about 700° C. at a chamber pressure between about 80 torr and about 160 torr. The polysilicon layer 342 may be doped or undoped.

FIG. 3C shows a tungsten layer 352 deposited by cyclical deposition over the polysilicon layer 342. Cyclical deposition of the tungsten layer 352 may be performed by the chamber described above in FIG. 2 and other suitable chambers. In one aspect, cyclical deposition of a tungsten layer 352 comprises sequentially and alternatively providing a tungsten containing compound and a reducing gas in a process chamber. While other attractive and/or boding forces may be at work and/or may contribute to the process, sequentially providing a tungsten containing compound and a reducing gas is believed to result in the alternating adsorption of monolayers of a tungsten containing compound and of monolayers of a reducing compound over a structure. The term “adsorption” as used herein is meant to include chemisorption, physisorption, or otherwise bonding, reaction, or adherence with so as to occupy a portion of an exposed surface of a substrate structure

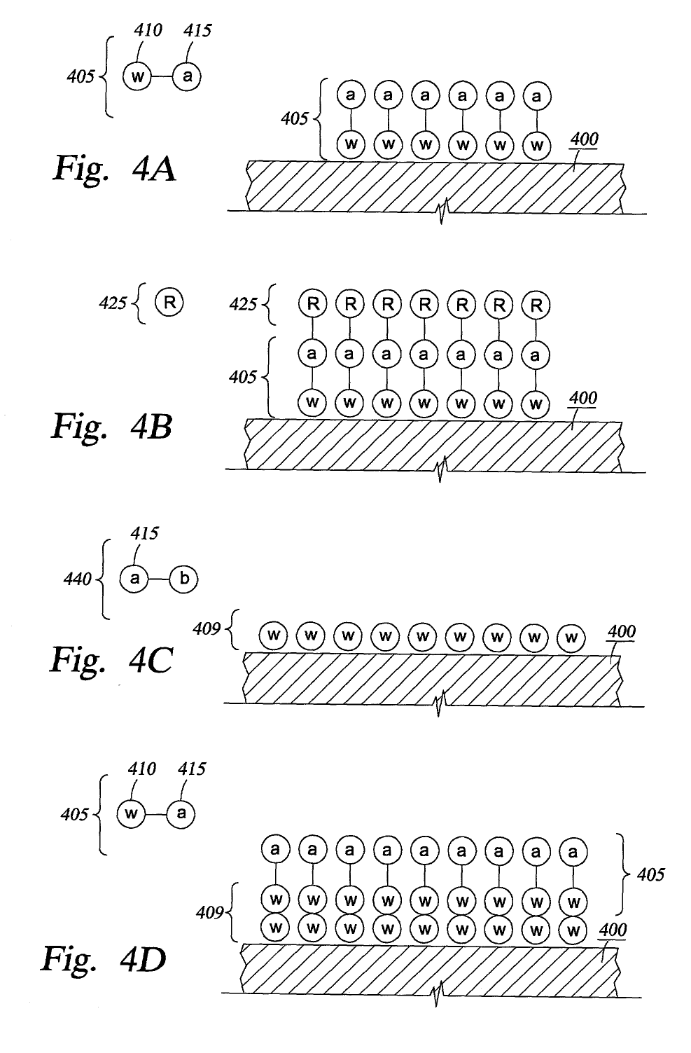

The composition and structure of precursors on a surface during atomic-layer deposition (ALD) is not precisely known. Not wishing to be bound by theory, FIGS. 4A-D are simplified drawings illustrating one embodiment of the alternating adsorption of monolayers of a tungsten containing compound and of monolayers of a reducing gas on an exemplary portion of a structure 400 in a stage of integrated circuit fabrication. In FIG. 4A, a monolayer of a tungsten containing compound 405 is adsorbed on the structure 400 by introducing a pulse of the tungsten containing compound 405 into a process chamber, such as into system 10 as described in FIG. 2. It is believed that the adsorption processes used to adsorb the monolayer of the tungsten containing compound 405 are self-limiting in that only one monolayer may be adsorbed onto the surface of the substrate 400 during a given pulse because the surface of the substrate has a finite number of sites for adsorbing the tungsten containing compound. Once the finite number of sites are occupied by the tungsten containing compound 405, further adsorption of any tungsten containing compound will be blocked. As a consequence, as a pulse of a tungsten containing compound 405 flows across the surface of a substrate, the tungsten containing compound 405 may adsorb onto the surface of the substrate. Any of the tungsten containing compound 405 not adsorbed will flow out of the chamber as a result of the vacuum system, carrier gas flow, and/or purge gas flow.

The tungsten containing compound 405 typically comprises tungsten atoms (W) 410 with one or more reactive species (a) 415. The tungsten containing compound 405 may be tungsten hexafluoride (WF₆), tungsten carbonyl (W(CO)₆), or other suitable tungsten containing compounds. The tungsten containing compound 405 may be provided as a gas or may be provided with the aid of a carrier gas. For example, the tungsten containing compound 405, such as WF₆, may be a gas and may be introduced with or without a carrier gas. Alternatively, the tungsten containing compound 405 may be a liquid and may be introduced by bubbling a carrier gas therethrough. Examples of carrier gases which may be used include, but are not limited to, helium (He), argon (Ar), nitrogen (N₂), hydrogen (H₂), and combinations thereof. The carrier gas may be provided as pulses to provide pulses of the tungsten containing compound 405. Alternatively, the carrier gas may be provided as a continuous flow into the chamber in which pulses of the tungsten containing compound 405 is provided by dosing the carrier gas with the tungsten containing compound.

After a pulse of a tungsten containing compound 405 is introduced into the chamber, a purge gas is introduced. Examples of purge gases which may be used include, but are not limited to, hydrogen (H₂), helium (He), argon (Ar), nitrogen (N₂), other gases, and combinations thereof. The purge gas may be provided as pulses or may be provided as a continuous flow into the chamber. The purge gas and the carrier gas may comprise or different gas flows or may comprise the same gas flow. If the purge gas and the carrier gas comprise different gas flows, the purge gas and the carrier gas preferably comprise the same composition.

Referring to FIG. 4B, after a purge gas has been introduced, a pulse of a reducing gas 425 is introduced into the process chamber in which the purge gas separates the pulse of the tungsten containing compound 405 and the pulse of the reducing gas 425. Suitable reducing gases may include for example, silane (SiH₄), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇), and decaborane (B₁₀H₃₀), among others. The reducing gas may be introduced alone or may be introduced with a carrier. For example, the reducing gas, such as diborane, may be a gas and may be introduced with or without a carrier gas. Alternatively, the reducing gas may be introduced by bubbling a carrier gas therethrough. Examples of carrier gases which may be used include, but are not limited to, helium (He), argon (Ar), nitrogen (N₂), hydrogen (H₂), and combinations thereof. The carrier gas may be provided as pulses to provide pulses of the reducing gas. Alternatively, the carrier gas may be provided as a continuous flow into the chamber in which pulses of the reducing gas is provided by dosing the carrier gas with the reducing gas. A monolayer of the reducing gas 425 may be adsorbed on the monolayer of the tungsten containing compound 405.

As shown in FIG. 4C, it is believed that the adsorbed monolayer of the reducing gas 425 reacts with the monolayer of the tungsten containing compound 405 to form a tungsten layer 409. The reactive species (a) 415 form by-products (ab) 440, that are transported from the substrate surface by the vacuum system, carrier gas flow, and/or purge gas flow. It is believed that the reaction of the reducing gas 425 with the tungsten containing compound 405 is self-limited since only one monolayer of the tungsten containing compound 405 was adsorbed onto the substrate surface. As a consequence, as a pulse of a reducing gas 425 flows across the surface of a substrate, the reducing gas 425 may adsorb onto the surface of the substrate. Any of the reducing gas 425 not adsorbed will flow out of the chamber as a result of the vacuum system, carrier gas, and/or purge gas. In another theory, the tungsten containing compound 405 may be in an intermediate state when on a surface of the substrate 400. In addition, the deposited tungsten layer 409 may also contain more than simply elements of tungsten.

After a pulse of a reducing gas 425 is introduced into the chamber, a purge gas may be introduced. Thereafter, as shown in FIG. 4D, the tungsten layer deposition sequence of alternating introduction of pulses of the tungsten containing compound 405 and of the reducing gas 425 separated by a purge gas may be repeated, if necessary, until a desired thickness of the tungsten layer 409 is achieved.

In one aspect, pulses of the tungsten containing compound 405 and the reducing gas 425 may be present at the same time in the chamber. For example, each pulse of the tungsten containing compound 405 and the reducing gas 425 and the purge gas flow therebetween may flow across the surface of the substrate as waves or zones present in the chamber at the same time but flowing across different portions of the substrate.

In FIGS. 4A-4D, the tungsten layer formation is depicted as starting with the adsorption of a monolayer of a tungsten containing compound on the substrate followed by a monolayer of a reducing gas. Alternatively, the tungsten layer formation may start with the adsorption of a monolayer of a reducing gas on the substrate followed by a monolayer of the tungsten containing compound. Furthermore, in an alternative embodiment, a pump evacuation alone between pulses of reactant gases may be used to prevent simultaneous introduction of the reactant gases and to provide for alternating exposure of the substrate to a plurality of reactants.

The time duration for the pulses of the tungsten containing compound, the reducing gas, and the purge gas are variable and depends on the volume capacity of a deposition chamber employed as well as a vacuum system coupled thereto. For example, (1) a lower chamber pressure of a gas may require a longer pulse time; (2) a lower gas flow rate may require a longer time for chamber pressure to rise and stabilize requiring a longer pulse time; and (3) a large-volume chamber may take longer to fill and longer for chamber pressure to stabilize thus requiring a longer pulse time. In general, while considering the volume of the chamber and chamber conditions, the time duration of a pulse of the tungsten containing compound or the reducing gas should be long enough for adsorption of a monolayer thereof. In general, the time duration of a pulse of the purge gas should be long enough to facilitate removal of the reaction by-products and/or any residual materials in the process chamber.

In general, the tungsten layer may be formed over a structure at a substrate temperature between about 20° C. and 800° C., and a chamber pressure less than about 100 torr. A pulse time of less than about 5 seconds for a tungsten containing compound and a pulse time of less than about 2 seconds for the reducing gas are typically sufficient to form the tungsten layer on the structure. A pulse time of about 2 seconds for a purge gas is typically sufficient to clean a surface of a substrate from reaction by-products as well as any residual materials for a following pulse of reactant to adsorb thereon.

One exemplary process of depositing a tungsten layer by cyclical deposition in a process chamber, such as the system 10 of FIG. 2 comprises sequentially providing pulses of tungsten hexafluoride (WF₆) and pulses of diborane (B₂H₆). The tungsten hexafluoride may be provided at an undiluted flow rate of between about 10 sccm about 400 sccm, preferably between about 20 sccm and 100 sccm, in pulses of about 1.0 second or less, preferably about 0.2 seconds or less. A carrier gas, such as an argon carrier gas, may be provided with the tungsten hexafluoride. The diborane may be provided at an undiluted flow rate between about 5 sccm and 150 sccm, preferably between about 5 sccm and about 25 sccm, in pulses of about 1.0 second or less, preferably about 0.2 seconds or less. A carrier gas, such as an argon carrier gas, may be provided with the diborane. Whether a pulse or a continuous flow, a purge gas, such as an Argon purge gas, is provided for a time period of about 1.0 second or less, preferably about 0.3 seconds or less, between the pulses of tungsten hexafluoride and the diborane. Preferably, the cycle time of introducing the tungsten hexafluoride and diborane separated by a purge gas is about 2 seconds or less. The substrate temperature may be maintained at a temperature between about 250° C. and about 350° C. at a chamber pressure of between about 1 torr and about 10 torr.

Another exemplary process of depositing a tungsten layer by cyclical deposition in a process chamber comprises sequentially providing pulses of tungsten hexafluoride (WF₆) and pulses of silane (SiH₄). The tungsten hexafluoride may be provided at an undiluted flow rate of between about 20 sccm and 100 sccm in pulses of about 1.0 second or less, preferably about 0.2 seconds or less. A carrier gas, such as an argon carrier gas, may be provided with the tungsten hexafluoride. The silane may be provided at an undiluted flow rate between about 10 sccm and 500 sccm, preferably between 50 sccm and 200 sccm, in pulses of about 1.0 second or less, preferably about 0.2 seconds or less. A carrier gas, such as an argon carrier gas, may be provided with the silane. Whether a pulse or a continuous flow, a purge gas, such as an Argon purge gas, is provided for a time period of about 1.0 second or less, preferably about 0.3 seconds or less between pulses of the tungsten hexafluoride and the silane. Preferably, the cycle time of introducing the tungsten hexafluoride and silane separated by a purge gas is about 2 seconds or less. The substrate temperature may be maintained at a temperature between about 300° C. and about 400° C. at a chamber pressure of between about 1 torr and about 10 torr.

After the tungsten layer 352 (FIG. 3C) has been deposited using any reducing gas, such as diborane or silane, the tungsten layer 352 may be annealed to form a tungsten silicide layer 362 from the tungsten layer 352 and from the polysilicon layer 342 (FIG. 3C) to serve as the second electrode in the trench capacitor. In the embodiment shown in FIG. 3D, the tungsten layer 352 is annealed so that the polysilicon layer 342 is only partially consumed to leave a thin polysilicon layer 343. In another embodiment (not shown), the tungsten layer 352 is annealed so that the polysilicon layer is entirely consumed. In another embodiment (now shown), one or more tungsten layers may be deposited in which each layer is annealed.

Annealing of the tungsten layer may be performed in any suitable anneal chamber, such as a Radiance Centura™ rapid thermal anneal chamber available from Applied Materials, Inc., located in Santa Clara, Calif. One exemplary process of annealing the tungsten layer 352 comprises annealing the tungsten layer 352 at a substrate temperature of between about 750° C. and about 1,000° C. for a time period of between about 45 seconds and about 120 seconds in a nitrogen gas (N₂) atmosphere, although other inert gas environments may be used, such as a noble gas environment. Another exemplary process of annealing the tungsten layer 352 comprises annealing the tungsten layer 352 in a furnace anneal chamber at a substrate temperature of between about 800° C. and about 900° C. for a time period of about 30 minutes. After the tungsten silicide layer 362 has been formed, a polysilicon layer 372 is deposited over the tungsten silicide layer 362 to fill the trench 314. The structure 302 may be further processed, such as to complete formation of the capacitor structure and to form other devices over the capacitor structure.

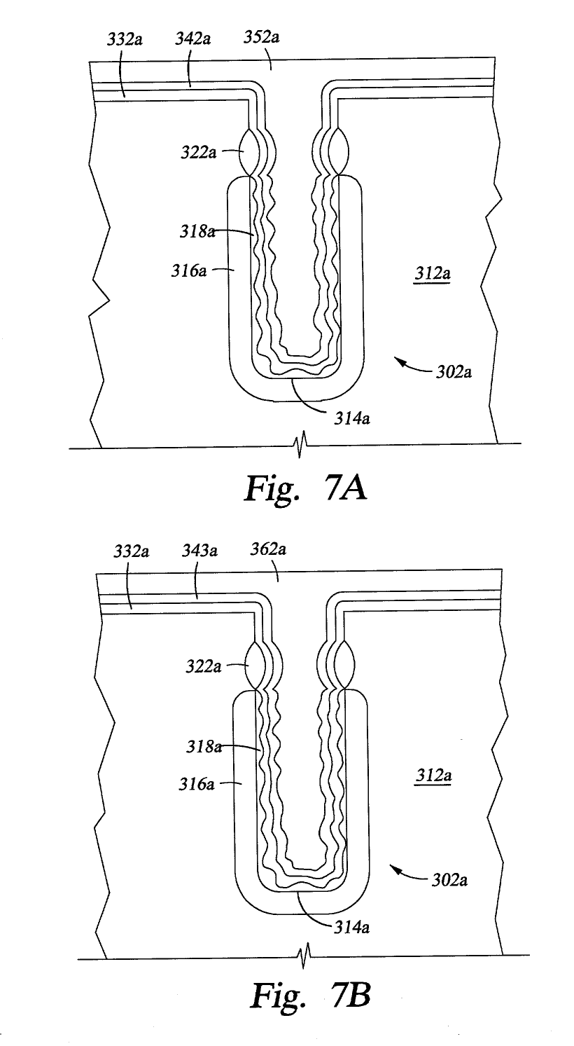

FIGS. 7A-B are cross sectional views of a substrate illustrating another embodiment of the sequential fabrication steps in the formation of a capacitor. Some of the layers of structure 302a are the same or similar to those described in reference to FIGS. 3A-3D, described above. Accordingly, like numbers have been used where appropriate. FIG. 7A shows a tungsten layer 352a deposited by cyclical deposition over the polysilicon layer 342a to fill the trench 314a. FIG. 7B shows a tungsten silicide layer 362a formed from the tungsten layer 352a and the polysilicon layer 342a after annealing. In the embodiment shown in FIG. 7B, the tungsten layer 352a is annealed so that the polysilicon layer 342a is only partially consumed to leave a thin polysilicon layer 343a. In other embodiments, the tungsten layer 352a is annealed so that the polysilicon layer is entirely consumed. The structure 302a may be further processed, such as to complete formation of the capacitor structure and to form other devices over the capacitor structure.

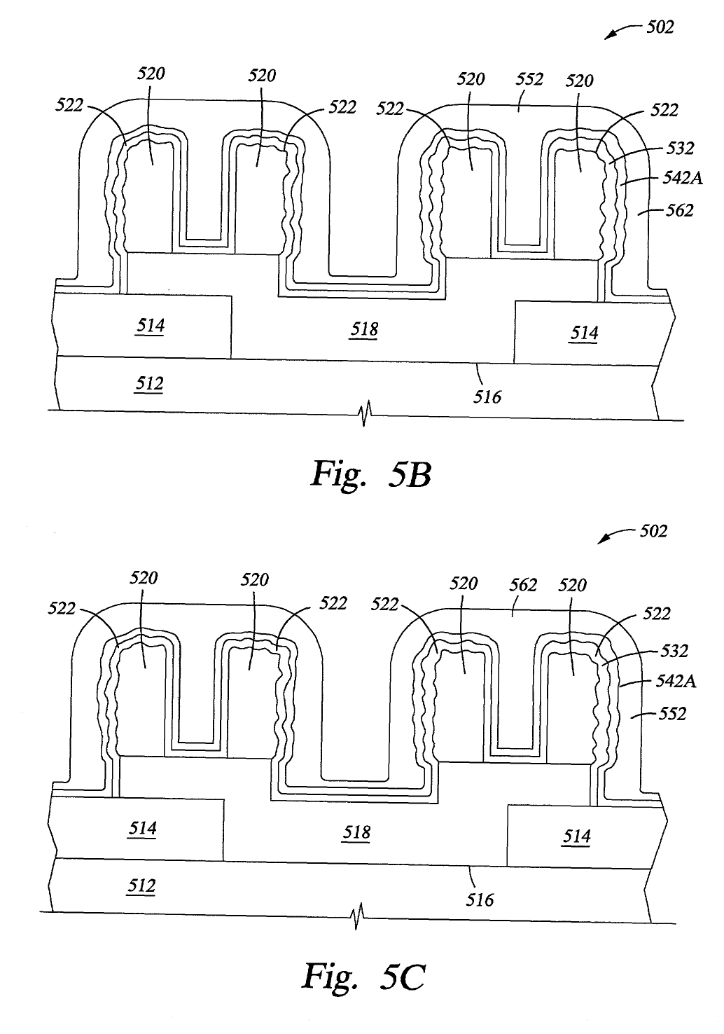

FIGS. 5A-C are cross-sectional views of a substrate illustrating still another embodiment of the sequential fabrication steps in the formation of a capacitor. FIG. 5A shows a structure 502 at one stage in the formation of a crown capacitor. In this embodiment, the structure 502 comprises a substrate 512, such as a silicon substrate, germanium substrate, or a gallium arsenide substrate, having a dielectric layer 514, such as a silicon oxide film, formed thereover. The dielectric layer 514 may include access devices formed therein. The dielectric layer 514 is patterned and etched to form an aperture 516. A polysilicon layer 518 is formed over the dielectric layer 514 and the aperture 516. The polysilicon layer 518 is doped with dopants, such as arsenic, antimony, phosphorus, boron, or other dopants. A polysilicon layer 520 having a hemi-spherical silicon grain surface or a rough surface 522 is formed over the polysilicon layer 518 by depositing an amorphous film over the polysilicon layer, etching the amorphous film and the polysilicon layer 518, and subjecting the amorphous film to a heat treatment. The polysilicon layer 520 may also be doped. The polysilicon layer 520 having a rough surface 522 and the polysilicon layer 518 form a crown structure which acts as a first electrode. The structure 502 further includes an insulating layer 532 comprising a dielectric material, such as Ta₂0₅, silicon oxide/silicon nitride/oxynitride (“ONO”), other dielectric materials, and other high dielectric constant materials. In one aspect, the insulating layer 532 preferably comprises Ta₂0₅ or other high dielectric constant materials because a high dielectric constant material allows the insulating layer 532 to be thinner and thus allows larger capacitance densities. Examples of other high dielectric constant materials include, but are not limited to, barium strontium titanate, barium titanate, lead zirconate titanate, lead lanthanium titanate, strontium titanate, and strontium bismuth titanate.

FIG. 5B is a schematic cross-section view of forming a second electrode over the crown structure of FIG. 5A. A polysilicon layer 542 is deposited over the insulating layer 532 and a tungsten layer 552 is deposited by cyclical deposition over the polysilicon layer 542 by methods as described elsewhere herein.

Referring to FIG. 5C, the tungsten layer 552 (FIG. 5B) may be annealed to form a tungsten silicide layer 562 from the tungsten layer 552 and from the polysilicon layer 542 (FIG. 5B) to serve as the second electrode in the capacitor. In one embodiment as shown in FIG. 5C, the tungsten layer 552 is annealed so that the polysilicon layer 542 is only partially consumed to leave a thin polysilicon layer 542A. In another embodiment (not shown), the tungsten layer 552 is annealed so that the polysilicon layer 542 is entirely consumed. The structure 502 may be further processed, such as to complete formation of the capacitor structure and to form other devices over the capacitor structure.

FIGS. 3A-D, 5A-C, and 7A-B illustrate the formation of specific embodiments of capacitors. The present invention includes forming a tungsten silicide electrode in other embodiments of trench capacitors, crown capacitors, and other capacitor structures including three-dimensional capacitors. Forming a tungsten silicide electrode by depositing tungsten by cyclical deposition may be used to advantage in depositing a conformal tungsten layer over difficult to cover topographies, such as over narrow openings, rough surfaces, and/or steep surfaces. For example, a conformal ALD tungsten layer may be used to advantage in forming trench capacitors over structures having a high aspect ratio, in forming crown capacitors to cover the varied topography of the crown structure, or in covering the rough topographies of hemi-spherical silicon grain layers or of materials deposited over hemi-spherical silicon grain layers. In one specific embodiment, a conformal ALD tungsten layer may be used to advantage in forming three-dimensional capacitors over structures having small openings, such as openings of about 0.15 μm or less, and/or over structures having high aspect ratios, such as an aspect ratio of about 15:1 or more, about 20:1 or more, or even about 40:1 or more. In one specific embodiment, in forming a capacitor structure in an aperture having an opening of about 0.15 μm or less and having an aspect ratio between about 15:1 and about 20:1, a polysilicon layer is deposited over the aperture to a sidewall and bottom coverage of between about 100 Å and about 200 Å and an ALD tungsten layer is deposited over the polysilicon layer to a sidewall and bottom coverage between about 50 Å and about 200 Å.

Platform for Forming Tungsten Silicide Electrode

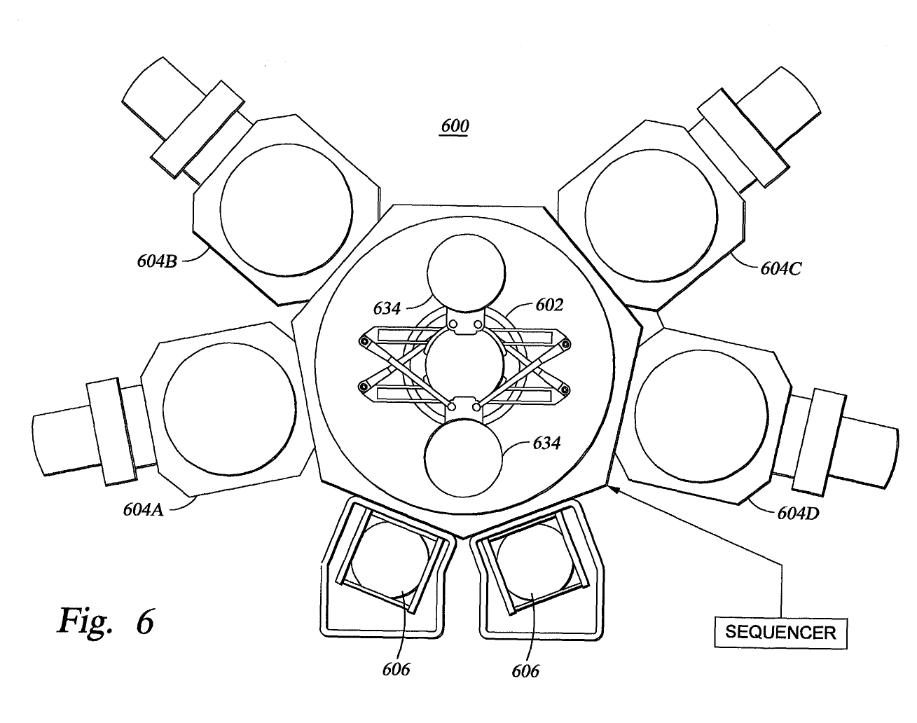

The processes as disclosed herein may be carried out in separate chambers or may be carried out in a multi-chamber processing system having a plurality of chambers. FIG. 6 is a schematic top view of one example of a multi-chamber processing system 600 which may be adapted to perform processes as disclosed herein. The apparatus is a Centura™ system and is commercially available from Applied Materials, Inc., located in Santa Clara, Calif. The particular embodiment of the system 600 is provided to illustrate the invention and should not be used to limit the scope of the invention.

The system 600 generally includes load lock chambers 606 for the transfer of substrates into and out from the system 600. Typically, since the system 600 is under vacuum, the load lock chambers 606 may “pump down” the substrates introduced into the system 200. A robot 602 may transfer the substrates between the load lock chambers 606 and processing chambers 604A, 604B, 604C, 604D. The robot 602 may be a dual blade robot having two blades 634 for transferring two substrates. Any of the processing chambers 604A, 604B, 604C, 604D may be removed from the system 600 if not necessary for the particular process to be performed by the system 600.

In one embodiment, the system 600 is configured to form a tungsten silicide electrode, such as tungsten silicide electrode 362, 362A, or 562 as described in relation to FIGS. 3A-3D, FIGS. 7A-B, or FIGS. 5A-5C. For example, one embodiment of system 600 comprises a process chamber 604A adapted to deposit a polysilicon layer, such as polysilicon layer 352 of FIG. 3B, polysilicon layer 352A of FIG. 7A, or polysilicon layer 552 of FIG. 5B; process chamber 604B may be adapted to deposit a tungsten layer by cyclical deposition, such as tungsten layer 362 of FIG. 3C, tungsten layer 362a of FIG. 7A, or tungsten layer 562 of FIG. 5B; and process chamber 604C may be adapted to anneal the tungsten layer to form a tungsten silicide layer, such as tungsten suicide layer 362 of FIG. 3D, tungsten silicide layer 362A of FIG. 7B, or tungsten silicide layer 562 of FIG. 5C. This embodiment of the system 600 may optionally further include process chamber 604D adapted to deposit a polysilicon layer, such as polysilicon layer 372 of FIG. 3D or may further include chamber 604A adapted to deposit both a polysilicon layer 352 of FIG. 3B and a polysilicon layer 372 of FIG. 3D. Other configurations of system 600 are possible. For example, the position of a particular processing chamber on the system 600 may be altered. Other embodiments of the system are within the scope of the present invention. For example, an Endure SL™ multi-chamber processing system, commercially available from Applied Materials, Inc., located in Santa Clara, Calif., may be used.

While foregoing is directed to the preferred embodiment of the present invention, other and further embodiments of the invention may be devised without departing from the basic scope thereof, and the scope thereof is determined by the claims that follow.

1. A method of forming an electrode for a three-dimensional capacitor structure, comprising:
depositing a polysilicon layer over a structure;
depositing a tungsten layer over the polysilicon layer by cyclical deposition; and
annealing the tungsten layer to form a tungsten silicide layer from the polysilicon layer and the tungsten layer.

2. The method of claim 1, wherein annealing the tungsten layer comprises partially consuming the polysilicon layer.

3. The method of claim 1, wherein annealing the tungsten layer comprises entirely consuming the polysilicon layer.

4. The method of claim 1, wherein the tungsten layer is deposited to a thickness between about 50 Å and about 200 Å.

5. The method of claim 1, wherein the tungsten layer is deposited over an aperture having an opening of about 0.15 μm or less.

6. The method of claim 1, wherein the tungsten layer is deposited over an aperture having an aspect ratio of about 15:1 or more.

7. The method of claim 6, wherein the tungsten layer is deposited over an aperture having an aspect ratio of about 20:1 or more.

8. The method of claim 7, wherein the tungsten layer is deposited over an aperture having an aspect ratio of about 40:1 or more.

9. The method of claim 1, wherein the structure is a crown structure.

10. The method of claim 1, wherein the structure is a trench structure.

11. A method of forming a capacitor structure, comprising:
forming a rough polysilicon surface;
depositing a high dielectric constant material layer over the rough polysilicon surface;
depositing a polysilicon layer over the high dielectric constant material layer;
depositing a tungsten layer over the polysilicon layer by cyclical deposition; and
annealing the tungsten layer to form a tungsten silicide layer from the polysilicon layer and the tungsten layer.

12. The method of claim 11, wherein annealing the tungsten layer comprises partially consuming the polysilicon layer.

13. The method of claim 11, wherein annealing the tungsten layer comprises entirely consuming the polysilicon layer.

14. The method of claim 11, wherein the tungsten layer is deposited to a thickness between about 50 Å and about 200 Å.

15. The method of claim 11, wherein the tungsten layer is deposited over an aperture having an opening of about 0.15 μm or less.

16. The method of claim 11, wherein the tungsten layer is deposited over an aperture having an aspect ratio of about 15:1 or more.

17. The method of claim 16, wherein the tungsten layer is deposited over an aperture having an aspect ratio of about 20:1 or more.

18. The method of claim 17, wherein the tungsten layer is deposited over an aperture having an aspect ratio of about 40:1 or more.

19. The method of claim 11, wherein the capacitor structure comprises a crown structure.

20. The method of claim 11, wherein the structure is a trench structure.

21. A three-dimensional capacitor, comprising:
a conformal tungsten silicide layer formed over a structure having an opening of about 0.15 μm or less.

22. The capacitor of claim 21, wherein the structure has an aspect ratio of about 15:1 or more.

23. The capacitor of claim 22, wherein the structure has an aspect ratio of about 20:1 or more.

24. The capacitor of claim 23, wherein the structure has an aspect ratio of about 40:1 or more.

25. The capacitor of claim 21, wherein the structure comprises a dielectric layer.

26. The capacitor of claim 25, wherein the dielectric layer comprises a high dielectric constant material layer.

27. The capacitor of claim 25, wherein the structure further comprises a rough polysilicon layer, the dielectric layer being formed over the rough polysilicon layer.

28. The capacitor of claim 25, further comprising a polysilicon layer between the dielectric layer and the tungsten silicide layer.

29. The capacitor of claim 21, wherein the three-dimensional capacitor comprises a trench capacitor.

30. A three-dimensional capacitor, comprising:
a rough polysilicon layer;
a high dielectric constant material layer formed over the rough polysilicon layer; and
a conformal tungsten silicide layer formed over the high dielectric constant material layer.

31. The capacitor of claim 30, further comprising a polysilicon layer between the high dielectric constant material layer and the tungsten silicide layer.

32. The capacitor of claim 30, wherein the three-dimensional capacitor comprises a crown capacitor.

33. The capacitor of claim 30, wherein the three-dimensional capacitor comprises a trench capacitor.

34. A system for processing a substrate, comprising:
a first chamber adapted to deposit a polysilicon layer;
a second chamber adapted to deposit a tungsten layer by cyclical deposition over the polysilicon layer; and
a third chamber adapted to anneal the tungsten layer.

35. The system of claim 34, wherein the third chamber is adapted to anneal the tungsten layer to form a tungsten silicide layer.

36. The system of claim 35, further comprising a fourth chamber adapted to deposit a polysilicon layer over the tungsten silicide layer.

37. The system of claim 35, wherein the first chamber is further adapted to deposit a second polysilicon layer over the tungsten silicide layer.
